(19) United States
(12) Patent Application Publication
(10) Pub. No.: US 2026/0255538 A1
(43) Pub. Date: Aug. 27, 2026

(54) DUO-PUMP LIQUID COOLING DEVICE

(71) Applicant: SHENZHEN APALTEK CO., LTD., Shenzhen (CN)

(72) Inventors: Qineng XIAO, Dongguan (CN); Dagao ZHENG, Shenzhen (CN); Dabiao LING, Shenzhen (CN)

(21) Appl. No.: 19/278,696

(22) Filed: Jul. 23, 2025

(30) Foreign Application Priority Data
Feb. 27, 2025 (CN) 2025102336636

(51) Int. Cl. H05K 7/20

(52) U.S. Cl. CPC H05K 7/20272

(57) ABSTRACT

A duo-pump liquid cooling device having a base seat, two pumps, a separating assembly, and a bottom seat is provided. The base seat is arranged on the bottom seat and has an inlet port, an outlet port, a concentrated cavity, two accommodated grooves, two channels, and an outlet groove. The inlet port is communicated to the concentrated cavity. The outlet port is communicated to the outlet groove. The accommodated grooves are communicated to the concentrated cavity and the channels. The pumps are corresponding to the accommodated grooves. The separating assembly has two through holes and a through slot group. A heat exchange chamber is formed between the separating assembly and the bottom seat and communicated to the channels and the outlet groove respectively through the through hole and the through slot group. The duo-pump liquid cooling device is therefore increasing coolant flow and improving heat dissipation efficiency.

### BACKGROUND

### Technical Field

The present disclosure relates to the field of liquid cooling, particularly to a duo-pump liquid cooling device.

### Description of related art

In a liquid cooling system, a coolant is sealed and filled in a closed loop to flow cyclically, and the coolant is used as a medium to carry a heat from a heat source to a heat dissipator for cooling and heat dissipation. Therefore, most liquid cooling systems use a pump to make the coolant to flow, and a heat dissipation efficiency of the entire liquid cooling system is better when a flow rate of the coolant is faster.

As electronic technology develops towards thinner and more powerful, the heat generated thereof has also increased significantly. However, the heat dissipator with single pump may only drive a limited flow rate of the coolant such that the heat dissipation efficiency thereof is insufficient. In addition, in order to cope with the thinner design, a capacity of the coolant may be reduced when the overall volume of the liquid cooling system is reduced. Therefore, after a period of use, the coolant would not be sufficient due to evaporation or leakage to affect the operation of the liquid cooling system.

In view of the above, the inventor seeks to overcome the aforementioned drawbacks associated with the current technology and aims to provide an effective solution through extensive researches along with utilization of academic principles and knowledge.

### SUMMARY

The primary objective of the present disclosure is to increase the flow rate of the coolant in the duo-pump liquid cooling device to improve heat dissipation efficiency and prevent the coolant from becoming insufficient due to evaporation or leakage after a period of use.

To accomplish the aforementioned objective, the present disclosure provides a duo-pump liquid cooling device having a base seat, a pair of pumps, a separating assembly, and a bottom seat. The base seat has an inlet port, an outlet port, a concentrated cavity, a pair of accommodated grooves, a pair of channels, and an outlet groove. The inlet port is communicated to the concentrated cavity. The outlet port is communicated to the outlet groove. Each of the accommodated grooves is arranged in parallel and communicated to the concentrated cavity. Each of the channels is communicated to each of the accommodated grooves and located on two sides of the concentrated cavity. Each of the pumps is configured to correspond to each of the accommodated grooves. The concentrated cavity is located between the separating assembly and each of the accommodated grooves. The separating assembly covers the concentrated cavity and has a pair of through holes and a through slot group. The base seat is arranged on the bottom seat to form a heat exchange chamber between the separating assembly and the bottom seat. Each of the channels is communicated to the heat exchange chamber through each of the through holes. The heat exchange chamber is communicated to the outlet groove through the through slot group.

Another aspect of the present disclosure provides that the bottom seat has a plurality of fins arranged in parallel, a plurality of flow channels is formed between each two of the fins, each of the fins and the separating assembly together separate the heat exchange chamber to each of the flow channels and a pair of inflow areas, two ends of each of the flow channels are communicated to each of the through holes through each of the inflow areas, each of the flow channels is communicated to the outlet groove through the through slot group.

Another aspect of the present disclosure provides that each of the through holes is configured to be located at a diagonal corner each of the fins.

Another aspect of the present disclosure provides that a location of the through slot group is located at a center of each of the fins.

Another aspect of the present disclosure provides that the separating assembly includes a separating plate and a diversion plate, the separating plate is arranged between the base seat and the diversion plate and has each of the through holes, the diversion plate is located between each of the through holes.

Another aspect of the present disclosure provides that the separating assembly further includes an abutting sheet, the abutting sheet is arranged between the diversion plate and the bottom seat, the abutting sheet has a pair of limiting baffles, each of the limiting baffles is limited on two opposite sides of the diversion plate.

Another aspect of the present disclosure provides that the separating assembly further includes a pair of stuffing blocks, each of the stuffing blocks is arranged on two opposite sides of the diversion plate, the through slot group is located between each of the stuffing blocks.

Another aspect of the present disclosure provides that the base seat includes a main body and a mounting frame, the main body has the inlet port, the outlet port, the concentrated cavity, each of the accommodated grooves, each of the channels, and the outlet groove, the mounting frame has a pair of mounting grooves, is arranged on the main body, and covers each of the accommodated grooves, each of the mounting grooves is configured to correspond to each of the accommodated grooves.

Another aspect of the present disclosure provides that each of the pumps includes a stator assembly and a rotor assembly, each of the rotor assemblies is arranged in each of the accommodated grooves, each of the stator assemblies is arranged in each of the mounting grooves.

Another aspect of the present disclosure provides that the inlet port and the outlet port are located on same side of the base seat.

In the duo-pump liquid cooling device of the present disclosure, the base seat forms the concentrated cavity, and the pumps are arranged in the accommodated grooves of the base seat in parallel. Therefore, the coolant may converge in the concentrated cavity after entering from the inlet port, and then the coolant sequentially enters the accommodated grooves, the channels, the through holes, the through slot group, and the heat exchange chamber by a suction force generated by the pumps when they are running. The duo-pump liquid cooling device of the present disclosure therefore increases the flow rate of the coolant therein to improve heat dissipation efficiency, prevents the coolant from becoming insufficient due to evaporation or leakage after a period of use, improves the sealing of the base seat, and reduces assembly complexity and maintenance costs.

### BRIEF DESCRIPTION OF THE DRAWINGS

FIG. 1 is an exploded view of the present disclosure;

FIG. 2 is another exploded view of the present disclosure;

FIG. 3 is a perspective appearance view of the present disclosure;

FIG. 4 is a cross-sectional front view of the present disclosure;

FIG. 5 is a cross-sectional view along A-A of FIG. 4;

FIG. 6 is a cross-sectional view along B-B of FIG. 4;

FIG. 7 is a cross-sectional top view of the concentrated cavity and the outlet groove of the present disclosure;

FIG. 8 is a cross-sectional view along C-C of FIG. 4; and

FIG. 9 is a cross-sectional view along D-D of FIG. 4.

### DETAILED DESCRIPTION

It is to be understood that the terms for indicating positions and the location relation, for example “front”, “rear”, “left”, “right”, “front end”, “rear end”, “distal end”, “longitudinal direction”, “lateral direction”, “vertical direction”, “top” and “bottom”, are based on the positions and the location relation disclosed in the drawings, and only used for disclosing the present disclosure and not used for indicating or implying the specified location of the device or the components or the specified structure and operation in certain location, thus the present disclosure is not intended to be limiting.

For example, the terms of “first”, “second”, “third”, “forth” and “fifth” are used for illustrating each unit, component, area, layer and/or part. The component, the unit, the area, the layer and/or the part are not limited by the terms. These terms are only used for separating the element, the assembly, the area, the layer, or the part. Unless being clearly indicated according to the whole specification, the terms for example “the first”, “the second”, “the third”, “the fourth” and “the fifth” are not used for implying the order or sequence.

As used herein and not otherwise defined, the terms "substantially" and "approximately" are used to describe and describe small changes. When used in connection with an event or situation, the terms may include the precise moment at which the event or situation occurs, as well as the event or situation occurring to a close approximation. For example, when combined with a numerical value, the terms may include a range of variation equal to or less than ±5% of the numerical value, such as equal to or less than ±4%, equal to or less than ±3%, equal to or less than ±2%, equal to or less than ±1%, equal to or less than ±0.5%, equal to or less than ±0.1%, or equal to or less than ±0.05%.

The technical contents of the present disclosure will become apparent with the detailed description of embodiments and the accompanied drawings as follows. However, it shall be noted that the accompanied drawings are for illustrative purposes only such that they shall not be used to restrict the scope of the present disclosure.

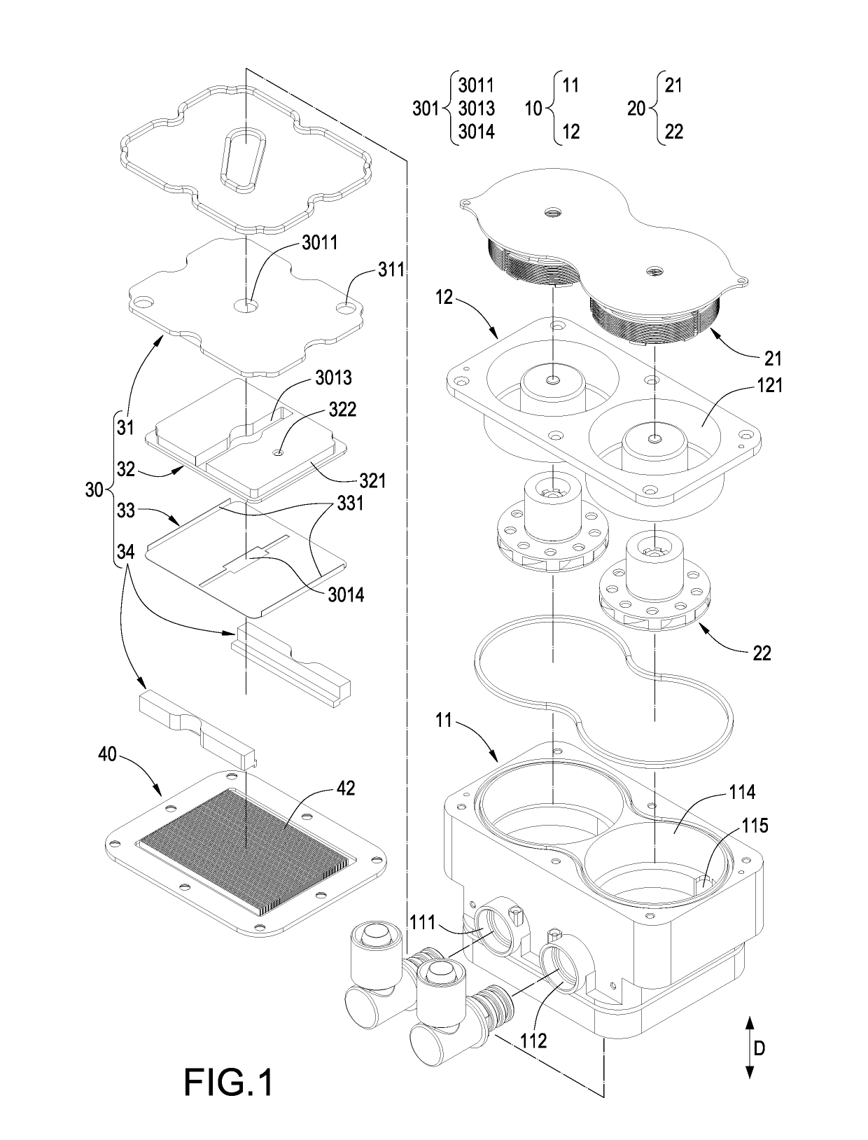

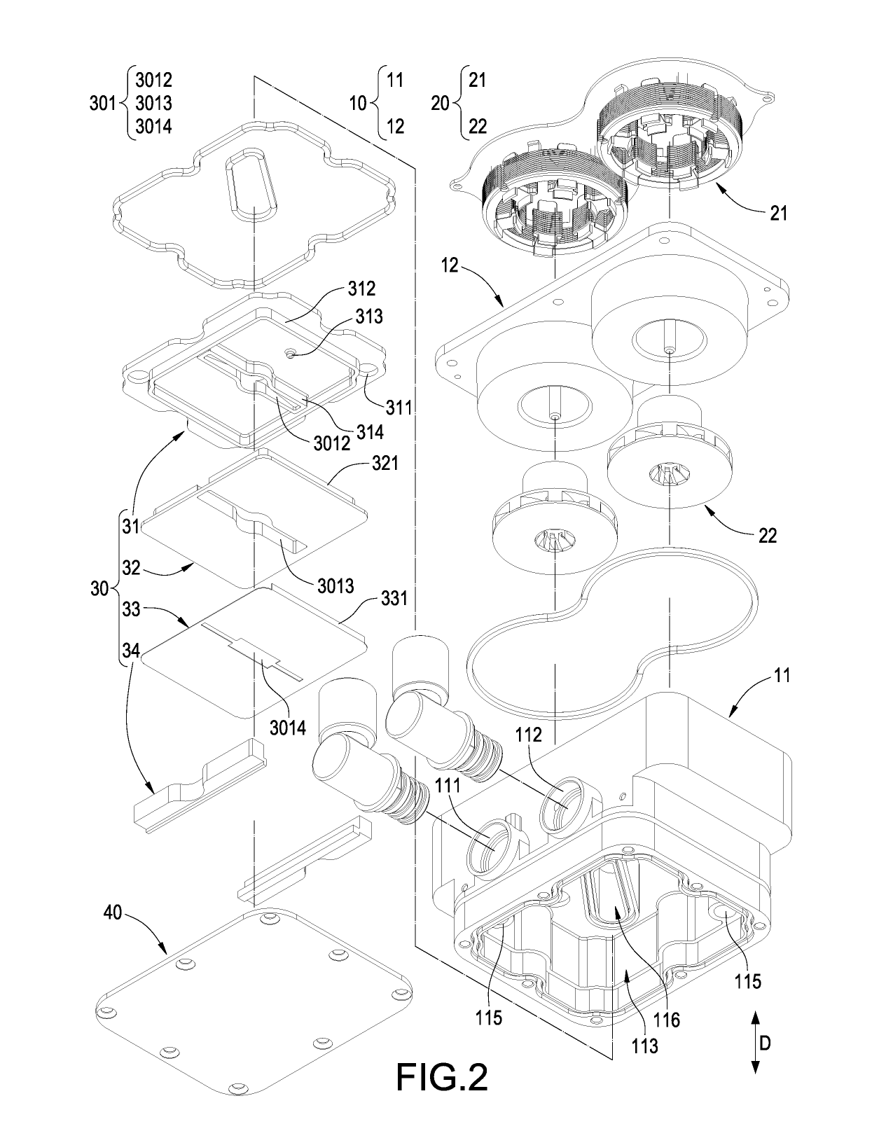

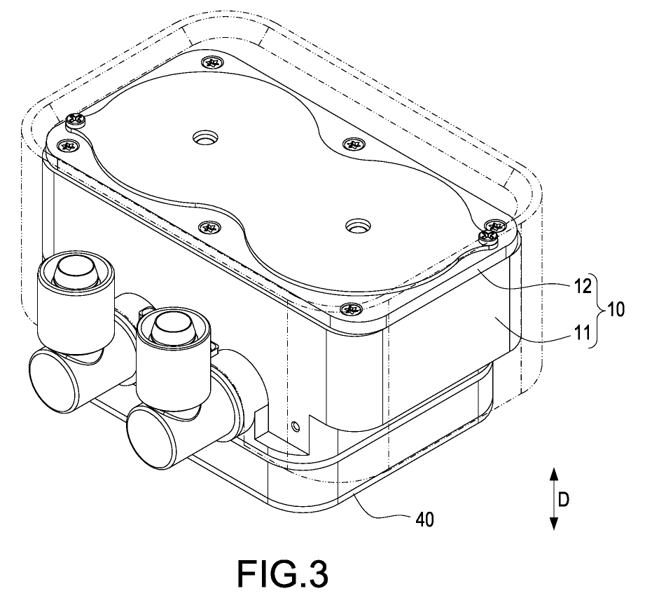

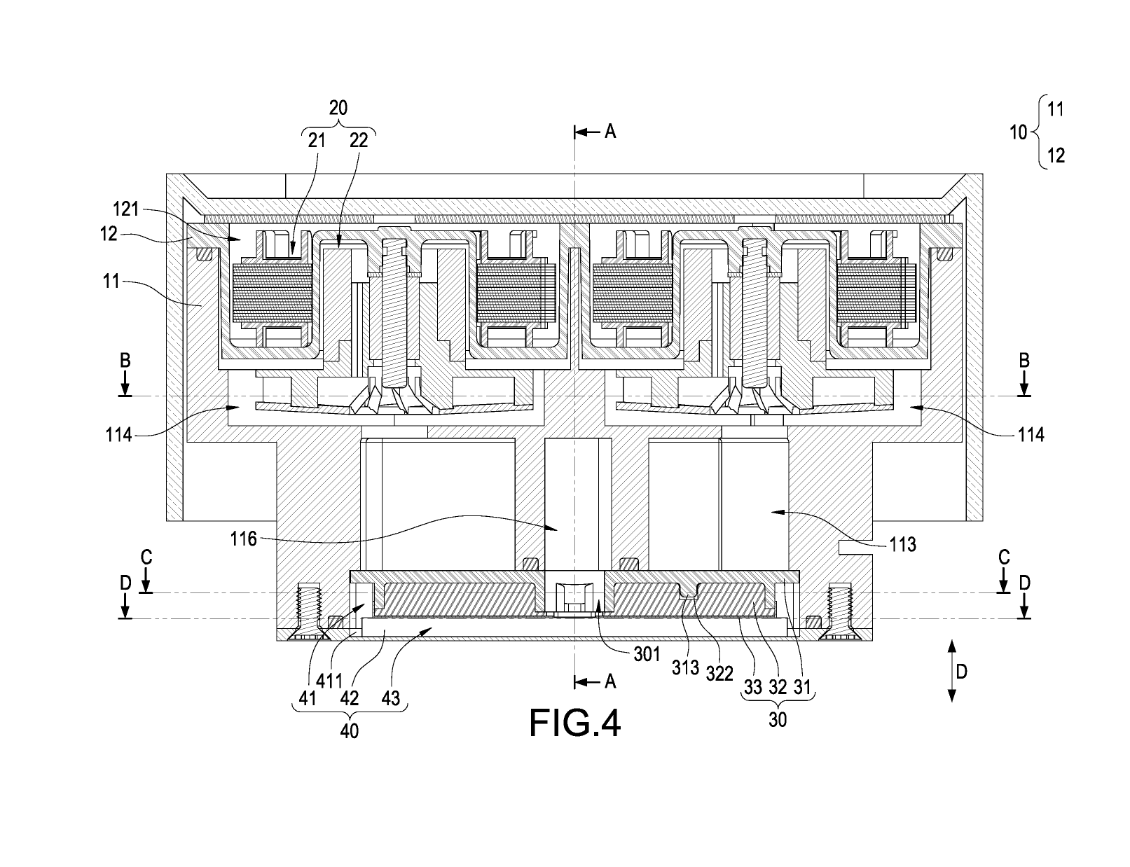

The present disclosure provides a duo-pump liquid cooling device for a coolant to flow through. Please refer to FIGS. 1, 2, 3, and 4, the duo-pump liquid cooling device of the present disclosure includes a base seat 10, a pair of pumps 20, a separating assembly 30, and a bottom seat 40.

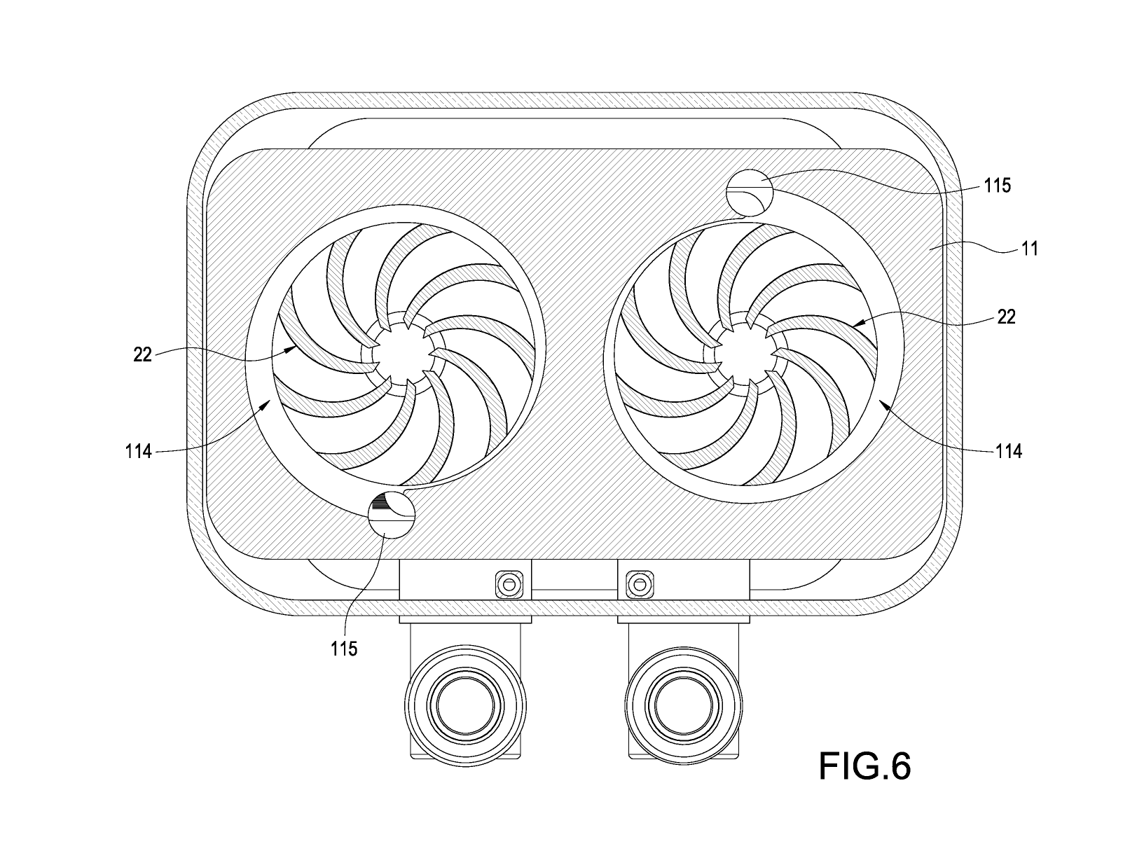

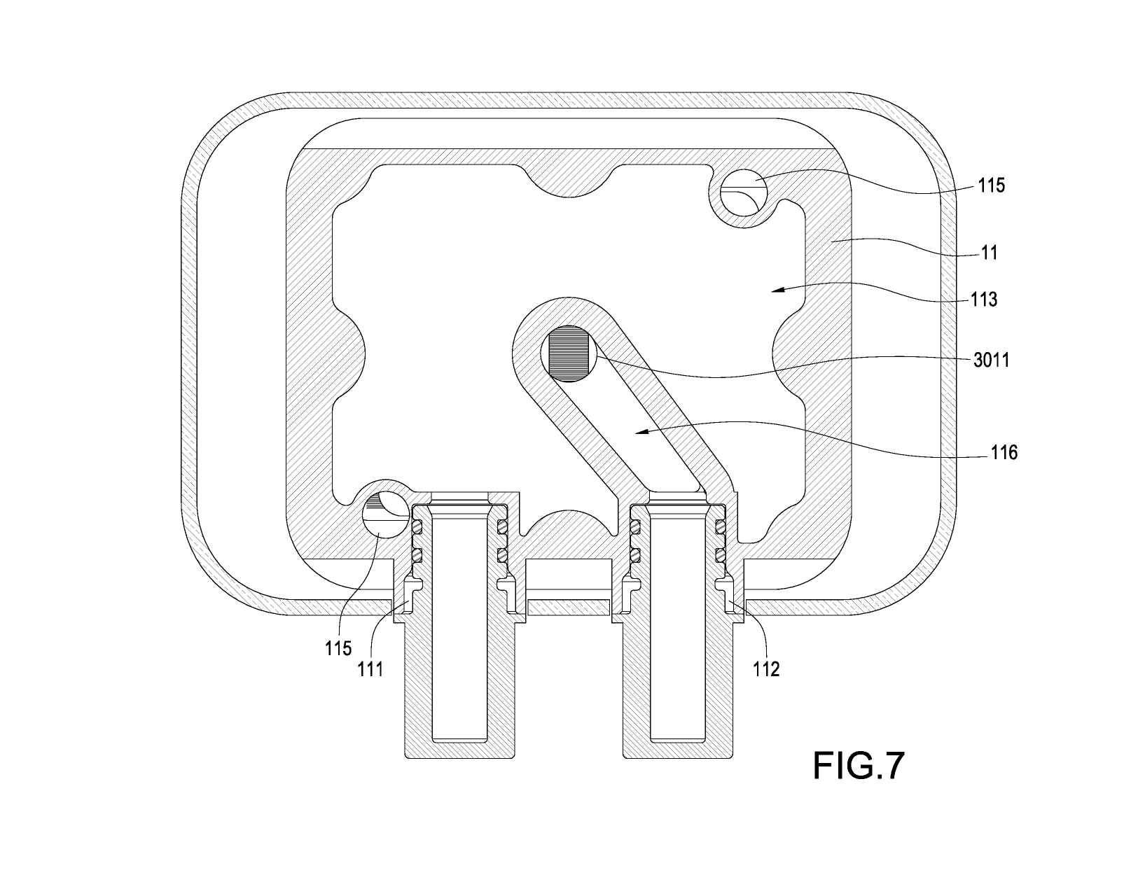

The base seat 10 is arranged on the bottom seat 40 along an up-down direction D. In the embodiment, the base seat 10 is rectangular, but the present disclosure is not limited to this embodiment. The base seat 10 has an inlet port 111, an outlet port 112, a concentrated cavity 113, a pair of accommodated grooves 114, a pair of channels 115, and an outlet groove 116. In the embodiment, the inlet port 111 and the outlet port 112 are both located on the same side of the base seat 10 such that a pair of infusion tubes (not shown in figures) respectively connected to the inlet port 111 and the outlet port 112 may be easily organized, but the inlet port 111 and the outlet port 112 may also be located on the different sides of the base seat 10 in other embodiments. Please refer to FIGS. 1, 4, 5, 6, and 7, the inlet port 111 is communicated to the concentrated cavity 113, and the outlet port 112 is communicated to the outlet groove 116. In detail, the concentrated cavity 113 and the outlet groove 116 are both formed on a bottom of the base seat 10, and the concentrated cavity 113 and the outlet groove 116 are not directly communicated to each other. Please refer to FIGS. 1, 4, 5, and 6, each of the accommodated grooves 114 is arranged on a top of the base seat 10 in parallel and respectively communicated to the concentrated cavity 113. In other words, each of the accommodated grooves 114 is located on the concentrated cavity 113 along the up-down direction D, and the inlet port 111 may be communicated to each of the accommodated grooves 114 through the concentrated cavity 113, as shown in FIGS. 6 and 7. Each of the channels 115 is configured to be corresponding to each of the accommodated grooves 114, communicated to each of the accommodated grooves 114, and located on two sides of the concentrated cavity 113. In the embodiment, the channels 115 are located at a diagonal position of the concentrated cavity 113, and each of the channels 115 is extended along the up-down direction D inward the base seat 10, but the present disclosure is not limited to this embodiment. For example, the channels 115 may also be oppositely located on two sides of the concentrated cavity 113, or each of the channels 115 may also be extended to be tilted relative to the up-down direction D in the base seat 10.

Please refer to FIGS. 1, 2, 3, 4, and 6, each of the pumps 20 is configured to correspond to each of the accommodated grooves 114. In detail, the base seat 10 includes a main body 11 and a mounting frame 12. The main body 11 is in a one-piece form, and the main body 11 has the inlet port 111, the outlet port 112, the concentrated cavity 113, the accommodated grooves 114, the channels 115, and the outlet groove 116. The mounting frame 12 has a pair of mounting grooves 121. The mounting frame 12 is arranged on a top of the main body 11 and covers each of the accommodated grooves 114, such that each of the mounting grooves 121 is configured to correspond to each of the accommodated grooves 114. In other words, the mounting grooves 121 and the accommodated grooves 114 are respectively located on two opposite sides of the mounting frame 12. Each of the pumps 20 includes a stator assembly 21 and a rotor assembly 22. Each of the rotor assemblies 22 is arranged in each of the accommodated grooves 114, and each of the stator assemblies 21 is arranged in each of the mounting grooves 121. In other words, each of the stator assemblies 21 is located on the corresponding rotor assembly 22 along the up-down direction D and surrounds a part of the corresponding rotor assembly 22. Since the specific structure and operation principle of the pumps 20 are well known in the art, they are not be described in detail.

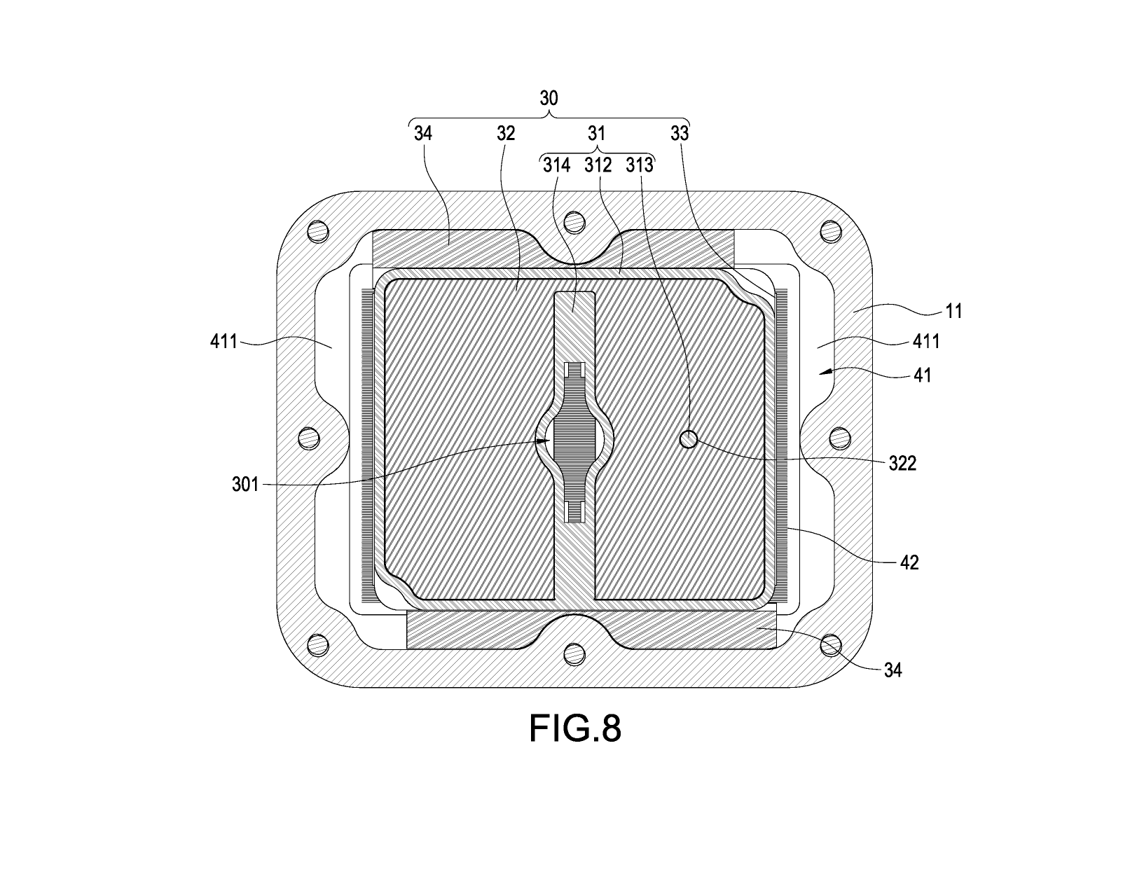

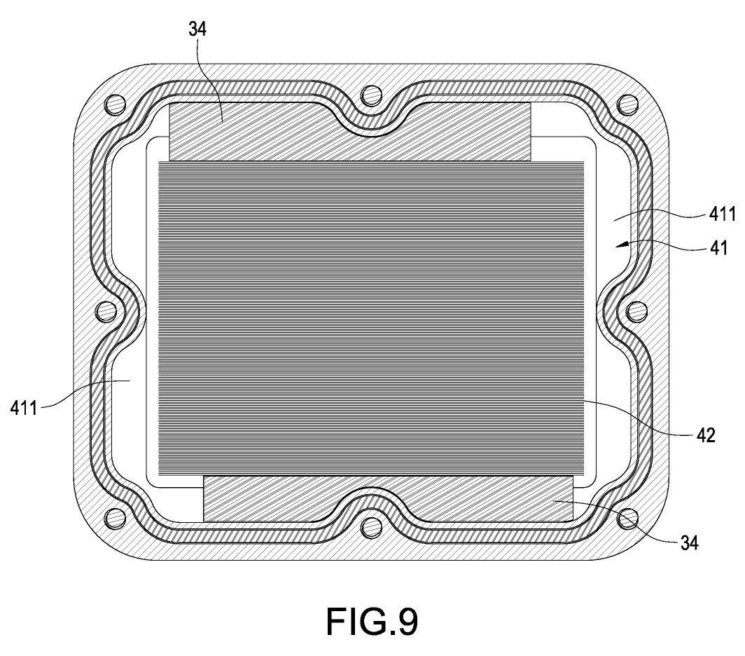

Please refer to FIGS. 1, 2, 3, 4, 5, 8, and 9, the separating assembly 30 covers a bottom of the concentrated cavity 113. In detail, the separating assembly 30 is abutted against between the bottom seat 40 and the base seat 10, such that the concentrated cavity 113 is substantially located between the separating assembly 30 and each of the accommodated grooves 114. The separating assembly 30 has a pair of through holes 311 and a through slot group 301. A heat exchange chamber 41 is formed between the separating assembly 30 and the bottom seat 40. Each of the channels 115 is communicated to the heat exchange chamber 41 through each of the through holes 311. The heat exchange chamber 41 is communicated to the outlet groove 116 through the through slot group 301. Therefore, the coolant may converge in the concentrated cavity 113 of the base seat 10 after the coolant entering the inlet port 111, and then the coolant is absorbed from the concentrated cavity 113 to the accommodated grooves 114 by a suction force generated by the pumps 20 when they are running. The coolant sequentially enters the heat exchange chamber 41 through the channels 115 and the through holes 311, enters the outlet groove 116 of the base seat 10 through the through slot group 301 of the separating assembly 30, and finally leaves the outlet port 112. Therefore, the arrangement of the concentrated cavity 113 may increase the flow rate of the coolant in the duo-pump liquid cooling device of the present disclosure to improve heat dissipation efficiency and prevent the coolant from becoming insufficient due to evaporation or leakage after a period of use. In addition, since the main body 11 of the base seat 10 is in a one-piece form instead of two parts form, the coolant is therefore avoiding leakage from a seam between the two parts to improve sealing and reduce assembly complexity and maintenance costs.

Details are provided as follows. The bottom seat 40 has a plurality of fins 42 arranged in parallel. Each of the fins 42 is arranged on a side of the bottom seat 40 facing the base seat 10 and the separating assembly 30, that is each of the fins 42 is arranged on a top of the bottom seat 40. A plurality of flow channels 43 parallel to each other is formed between each two of the fins 42. Two ends of each of the flow channels 43 are communicated to each of the through holes 311, and each of the flow channels 43 is communicated to the outlet groove 116 of the base seat 10 through the through slot group 301 of the separating assembly 30. In detail, the fins 42 and a part of the separating assembly 30 together separate the heat exchange chamber 41 to the flow channels 43 and a pair of inflow areas 411. Two ends of each of the flow channels 43 are respectively communicated to each of the inflow areas 411, that is the fins 42 and the flow channels 43 are all perpendicular between the inflow areas 411. In other words, part of the separating assembly 30 and the inflow areas 411 are arranged on an outer periphery of the fins 42 and the flow channels 43 to surround them. Each of the through holes 311 is communicated to each of the flow channels 43 through the inflow areas 411. In the embodiment, the through holes 311 are located at a diagonal position of the fins 42 such that the coolant may evenly flow into each of the flow channels 43 from each of the inflow areas 411, but the present disclosure is not limited to this embodiment. In addition, in the embodiment, a location of the through slot group 301 is located at a center of the fins 42, such that the coolant may converge at the center of the fins 42 to enter the through slot group 301 after entering from the two ends of the flow channels 43. Therefore, when the coolant enters the heat exchange chamber 41 through the channels 151 and the through holes 311, the coolant first enters the inflow areas 411, the coolant then flows into each of the flow channels 43 between each of the fins 42, and the coolant finally leaves the heat exchange chamber 41 from the through slot group 301 of the separating assembly 30.

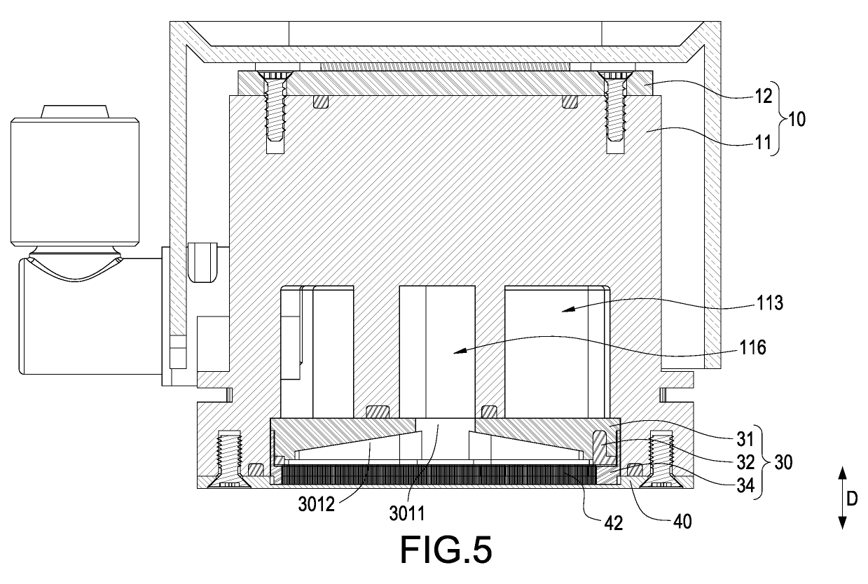

Please refer to FIGS. 1, 2, 4, 5, 8, and 9, the separating assembly 30 includes a separating plate 31, a diversion plate 32, an abutting sheet 33, and a pair of stuffing blocks 34. In the embodiment, the separating plate 31 and the abutting sheet 33 are both made of metal, the diversion plate 32 and the stuffing blocks 34 are made of silicone or rubber, but the present disclosure is not limited to this embodiment. Each of the stuffing blocks 34 is arranged on the bottom seat 40, parallel to the fins 42, and located on two sides of the fins 42. In the embodiment, as shown in FIG. 5, a cross-sectional shape of each of the stuffing blocks 34 along the inlet port 111 or the outlet port 112 is lightning shaped, and the stuffing blocks 34 are arranged oppositely to each other, such that the stuffing blocks 34 may be placed on two steps of two sides of the bottom seat 40 to carry the abutting sheet 33. The separating plate 31 is abutted against and arranged between the base seat 10 and the diversion plate 32, and the separating plate 31 has the through holes 311. The abutting sheet 33 is arranged on the fins 42 of the bottom seat 40 and the stuffing blocks 34 along the up-down direction D. The diversion plate 32 is abutted against and arranged between the abutting sheet 33 and the separating plate 31 and located between the through holes 311 and the inflow areas 411. In other words, the abutting sheet 33 is arranged between the diversion plate 32 and the fins 42 and the stuffing blocks 34 of the bottom seat 40, and the stuffing blocks 34 are arranged on two opposite sides of the diversion plate 32 to make the through slot group 301 to be located between the stuffing blocks 34. Therefore, the stuffing blocks 34, the abutting sheet 33, the diversion plate 32, and the separating plate 31 of the separating assembly 30 are sequentially stacked on the bottom seat 40 along the up-down direction D.

Details are provided as follows. The separating plate 31 has a surrounding wall 312. The diversion plate 32 has a fixing groove 321. In detail, the surrounding wall 312 is extended from a side of the separating plate 31 facing the diversion plate 32 to be rectangular shaped. The fixing groove 321 is concave from a top periphery of the diversion plate 32 to be a hollow-rectangular groove. The surrounding wall 312 of the separating plate 31 is fixed to the fixing groove 321 of the diversion plate 32, so as to limit a top of the diversion plate 32 in the surrounding wall 312 of a bottom of the separating plate 31. In the embodiment, the separating plate 31 has a positioning block 313 extended from a side of the separating plate 31 facing the diversion plate 32. The diversion plate 32 has a positioning hole 322 located on a side of the diversion plate 32 facing the separating plate 31. The positioning block 313 is fixed in the positioning hole 322 to further position the separating plate 31 and the diversion plate 32. In another embodiment, the positioning block 313 may also be arranged on the diversion plate 32, and the positioning hole 322 may also be arranged on the separating plate 31.

In addition, the abutting sheet 33 has a pair of limiting baffles 331 located on two opposite sides thereof. Each of the limiting baffles 331 of the abutting sheet 33 is perpendicularly extended toward the diversion plate 32 along the up-down direction D such that the diversion plate 32 is limited between the limiting baffles 331. In other words, the limiting baffles 331 of the abutting sheet 33 limit two opposite sides of the diversion plate 32, and the stuffing blocks 34 limit the other two sides of the diversion plate 32 to further restrict the diversion plate 32 from moving forward, backward, left, or right.

Therefore, the separating plate 31 and the diversion plate 32 may be positioned relative to each other without relative displacement, and the diversion plate 32 may also be stably clamped between the separating plate 31 and the abutting sheet 33 to ensure that the diversion plate 32 cannot move along the up-down direction D, and the diversion plate 32, the stuffing blocks 34, and the abutting sheet 33 may also be positioned relative to each other without relative displacement. In addition, since the diversion plate 32 made of silicone or rubber is clamped between the separating plate 31 and the abutting sheet 33 that are made of metal, the diversion plate 32 may effectively prevent from being deformed or displaced by a strong upward impact of the coolant along the up-down direction D, so as to ensure the coolant may flow stably when passing through the separating assembly 30.

Details are provided as follows. Please refer to FIGS. 1, 2, 4 , 5, and 8 again, the through slot group 301 includes a penetration hole 3011, a first through slot 3012, a second through slot 3013, and a third through slot 3014. The penetration hole 3011 and the first through slot 3012 are defined on the separating plate 31. In detail, the penetration hole 3011 is a circle hole and passes through the separating plate 31 along the up-down direction D, and the first through slot 3012 is defined on a bottom of the separating plate 31 and communicated to the penetration hole 3011. In the embodiment, as shown in FIG. 5, the first through slot 3012 is extended slantly from the bottom of the separating plate 31 toward the penetration hole 3011 and gradually shrinking, such that the coolant may easily converge to the penetration hole 3011 without blockage, but the present disclosure is not limited to this embodiment. The separating plate 31 has an embedded block 314. The embedded block 314 is extended from a side of the separating plate 31 facing the diversion plate 32 and surrounds the first through slot 3012. The second through slot 3013 passes through the diversion plate 32 along the up-down direction D, and a shape of the second through slot 3013 is corresponding to a shape of the embedded block 314. Therefore, the embedded block 314 of the separating plate 31 is fixed to the second through slot 3013 of the diversion plate 32 to further position the separating plate 31 and the diversion plate 32. The first through slot 3012 is located in the embedded block 314 and communicated to the second through slot 3013. In the embodiment, a center of the first through slot 3012 is a circle hole, two opposite sides of the first through slot 3012 respectively extend a strip hole, and a diameter of the circle hole at the center of the first through slot 3012 is larger than a width of each of the strip holes at two opposite sides of the first through slot 3012. However, the present disclosure is not limited to this embodiment. The third through slot 3014 passes through the abutting sheet 33 along the up-down direction D. The third through slot 3014 is communicated to the second through slot 3013 of the diversion plate 32 and the first through slot 3012 of the separating plate 31, so as to be communicated to the penetration hole 3011 of the separating plate 31. In the embodiment, the third through slot 3014 is elongated strip shaped to form two narrow sections and a wide section. A location of the wide section is approximately corresponding to a location of the circle hole at the center of the first through slot 3012. The narrow sections are communicated to two opposite sides of the wide section and approximately corresponding to the strip holes of the first through slot 3012. However, the present disclosure is not limited to this embodiment.

It is worth noting that the through slot group 301 of the separating assembly 30 is substantially perpendicular to each of the fins 42 and each of the flow channels 43, and the through slot group 301 is approximately located at a center of each of the fins 42 and each of the flow channels 43. In detail, as FIGS. 1, 2, 3, 4, 5, and 8 for example. Each of the fins 42 and each of the flow channels 43 is parallel to a front-rear direction (a defined direction of the inlet port 111 and the outlet port 112) of the base seat 10 and the bottom seat 40, and the first through slot 3012 and the third through slot 3014 of the through slot group 301 are parallel to a left-right direction of the base seat 10 and the bottom seat 40 such that the first through slot 3012 and the third through slot 3014 are both perpendicular to each of the fins 42 and each of the flow channels 43. Therefore, the coolant will flow to the center of each of the fins 42 and each of the flow channels 43 when the coolant enters each of the flow channels 43 from each of the inflow areas 411, and then the coolant sequentially enters the third through slot 3014, the second through slot 3013, the first through slot 3012, and the penetration hole 3011 along the up-down direction D to pass through the separating assembly 30 and enter the outlet groove 116 of the base seat 10. In addition, when the coolant passes through the third through slot 3014 and the first through slot 3012 of the separating assembly 30, the coolant will gradually converge toward the wide section and the circle hole to flow out of the penetration hole 3011 of the separating plate 31 because of affecting by the narrow sections and the strip holes.

In the duo-pump liquid cooling device of the present disclosure, the base seat 10 forms the concentrated cavity 113, and the pumps 20 are arranged in the accommodated grooves 114 of the base seat 10 in parallel. Therefore, the coolant may converge in the concentrated cavity 113 after entering the inlet port 111, and then the coolant sequentially enters the accommodated grooves 114, the channels 115, the through holes 311, the through slot group 301, and the heat exchange chamber 41 by a suction force generated by the pumps 20 when they are running. The duo-pump liquid cooling device of the present disclosure therefore increases the flow rate of the coolant therein to improve heat dissipation efficiency, prevents the coolant from becoming insufficient due to evaporation or leakage after a period of use, improves the sealing of the base seat 10, and reduces assembly complexity and maintenance costs.

It shall be understood that the present disclosure may have other types of embodiments, and a person with ordinary skills in the art of the technical field of the present disclosure may make various changes and modifications corresponding to the present disclosure without deviating the principle and substance of the present disclosure; however, such corresponding changes and modification shall be considered to be within the claimed scope of the present disclosure.

What is claimed is:

1. A duo-pump liquid cooling device, comprising:
a base seat, comprising an inlet port, an outlet port, a concentrated cavity, a pair of accommodated grooves, a pair of channels, and an outlet groove, the inlet port communicated to the concentrated cavity, the outlet port communicated to the outlet groove, each of the accommodated grooves arranged in parallel and communicated to the concentrated cavity, each of the channels communicated to each of the accommodated grooves and located on two sides of the concentrated cavity;
a pair of pumps, configured to correspond to each of the accommodated grooves;
a separating assembly, wherein the concentrated cavity is located between the separating assembly and each of the accommodated grooves, the separating assembly covers the concentrated cavity and comprises a pair of through holes and a through slot group; and
a bottom seat, wherein the base seat is arranged on the bottom seat to form a heat exchange chamber between the separating assembly and the bottom seat, each of the channels is communicated to the heat exchange chamber through each of the through holes, the heat exchange chamber is communicated to the outlet groove through the through slot group.

2. The duo-pump liquid cooling device according to claim 1, wherein the bottom seat comprises a plurality of fins arranged in parallel, a plurality of flow channels is formed between each two of the fins, each of the fins and the separating assembly together separate the heat exchange chamber to each of the flow channels and a pair of inflow areas, two ends of each of the flow channels are communicated to each of the through holes through each of the inflow areas, each of the flow channels is communicated to the outlet groove through the through slot group.

3. The duo-pump liquid cooling device according to claim 2, wherein each of the through holes is configured to be located at a diagonal corner each of the fins.

4. The duo-pump liquid cooling device according to claim 2, wherein a location of the through slot group is located at a center of each of the fins.

5. The duo-pump liquid cooling device according to claim 1, wherein the separating assembly comprises a separating plate and a diversion plate, the separating plate is arranged between the base seat and the diversion plate and comprises each of the through holes, the diversion plate is located between each of the through holes.

6. The duo-pump liquid cooling device according to claim 5, wherein the separating assembly further comprises an abutting sheet, the abutting sheet is arranged between the diversion plate and the bottom seat, the abutting sheet comprises a pair of limiting baffles, each of the limiting baffles is limited on two opposite sides of the diversion plate.

7. The duo-pump liquid cooling device according to claim 5, wherein the separating assembly further comprises a pair of stuffing blocks, each of the stuffing blocks is arranged on two opposite sides of the diversion plate, the through slot group is located between each of the stuffing blocks.

8. The duo-pump liquid cooling device according to claim 1, wherein the base seat comprises a main body and a mounting frame, the main body comprises the inlet port, the outlet port, the concentrated cavity, each of the accommodated grooves, each of the channels, and the outlet groove, the mounting frame comprises a pair of mounting grooves, is arranged on the main body, and covers each of the accommodated grooves, each of the mounting grooves is configured to correspond to each of the accommodated grooves.

9. The duo-pump liquid cooling device according to claim 8, wherein each of the pumps comprises a stator assembly and a rotor assembly, each of the rotor assemblies is arranged in each of the accommodated grooves, each of the stator assemblies is arranged in each of the mounting grooves.

10. The duo-pump liquid cooling device according to claim 1, wherein the inlet port and the outlet port are located on same side of the base seat.
